(19) United States
(12) Patent Application Publication
(10) Pub. No.: US 2025/0110263 A1
(43) Pub. Date: Apr. 3, 2025

(54) OPTICAL DEVICES AND METHOD OF MANUFACTURING OPTICAL DEVICES

(71) Applicant: STMicroelectronics International N.V., Geneva (CH)

(72) Inventors: Simon GUILLAUMET, Grenoble (FR); Stephanie AUDRAN, Le Touvet (FR); Benjamin VIANNE, Le Cheylas (FR); James Peter Drummond DOWNING, Doune (GB)

(73) Assignee: STMicroelectronics International N.V., Geneva (CH)

(21) Appl. No.: 18/894,603

(22) Filed: Sep. 24, 2024

(30) Foreign Application Priority Data
Sep. 29, 2023 (FR) 2310433

(51) Int. Cl. G02B 1/116; B82Y 20/00; B82Y 40/00; G02B 1/00

(52) U.S. Cl. CPC G02B 1/116; B82Y 20/00; B82Y 40/00; G02B 1/002

(57) ABSTRACT

An optical device includes a metasurface formed by a metasurface substrate having at least a first metasurface layer made of a first material and an array of pillars extending through the first metasurface layer. The pillars are made of a second material different from the first material. The metasurface has a first face and a second face opposite the first face. A first anti-reflection stack is positioned over the first face of the metasurface. The first anti-reflection stack has a third face and a fourth face opposite the third face and positioned over the first face of the metasurface. A metal trace has a portion which is exposed at the third face of the first anti-reflection stack.

### PRIORITY CLAIM

This application claims the priority benefit of French Application for Patent No. 2310433, filed on Sep. 29, 2023, the content of which is hereby incorporated by reference in its entirety to the maximum extent allowable by law.

### TECHNICAL FIELD

The present disclosure relates generally to optical devices and, more particularly, the manufacturing of optical devices.

### BACKGROUND

Optical devices, such lenses, diffusers, filters, beam shapers, mirrors etc., are currently used nowadays and are more and more used in optoelectronic devices or systems.

It would be desirable to be able to at least partly improve certain aspects of optical devices and of the manufacturing of optical devices, in particular optical devices including optical metasurfaces.

There is a need for improving the manufacturing of optical devices, in particular optical devices including optical metasurfaces.

There is a need to address all or some of the drawbacks of known optical devices and of known method of manufacturing of optical devices.

### SUMMARY

One embodiment provides an optical device comprising: a metasurface comprising a metasurface substrate having at least a first metasurface layer made of a first material, and an array of pillars extending through the first metasurface layer, the pillars being made of a second material different from the first material, the metasurface having a first face and a second face opposite the first face; a first anti-reflection stack having a first face and a second face opposite the first face, wherein the second face of the first anti-reflection stack is positioned over the first face of the metasurface; and a metal trace having a portion which is exposed at the first face of the first anti-reflection stack.

According to an embodiment, the first metasurface layer extends at the first face of the metasurface.

According to an embodiment, the metal trace is included, for example embedded, in the metasurface substrate, the optical device comprising a first opening extending through the first anti-reflection stack and the metasurface substrate down to the portion of the metal trace which is exposed.

According to an embodiment, the metal trace is embedded in a second metasurface layer of the metasurface substrate in contact with the first metasurface layer, the metasurface substrate further comprising a third metasurface layer in contact with the second metasurface layer and covering the metal trace, the second metasurface layer being between the first metasurface layer and the third metasurface layer.

According to an embodiment, the metal trace is positioned over the first face of the first anti-reflection stack, for example corresponding to at least a portion of a contact pad.

According to an embodiment, the optical device further comprises a transparent substrate, for example a glass substrate, the second face of the metasurface being over a first face of the transparent substrate.

According to an embodiment, the optical device further comprises a second anti-reflection layer, wherein a second face of the transparent substrate, opposite the first face of said transparent substrate, is over said second anti-reflection layer.

One embodiment provides a method of manufacturing of an optical device, the method comprising: forming a metasurface comprising a metasurface substrate including at least a first metasurface layer made of a first material, and an array of pillars extending through the first metasurface layer, the pillars being made of a second material different from the first material, the metasurface having a first face and a second face opposite the first face; forming a first anti-reflection stack over the first face of the metasurface, the first anti-reflection stack having a first face and a second face opposite the first face, wherein the second face of the first anti-reflection stack is positioned over the metasurface; and forming a metal trace having a portion which is exposed at the first face of the first anti-reflection stack.

According to an embodiment, forming the metasurface and the first anti-reflection stack comprises: forming on a silicon wafer a first stack comprising at least a first layer made of a third material different from the first material, the first stack having a first face corresponding to a first face of the first layer, and a second face opposite the first face and facing the silicon wafer; forming on the first face of the first layer the first metasurface layer; forming second openings extending through the first metasurface layer; filling the second openings with a filling material, for example an amorphous silicon or a polycrystalline silicon, to form the array of pillars, and for example annealing the filling material; forming a second metasurface layer of the metasurface substrate on the first metasurface layer in order to at least cover the array of pillars; removing the silicon wafer; and forming a second stack comprising at least a second layer on the second face of the first stack, the first stack and the second stack forming the first anti-reflection stack.

According to an embodiment, the forming of the metal trace with the exposed portion is performed after the forming of the second metasurface layer and before the removing of the silicon wafer, and comprises: forming a metal trace in the metasurface substrate, for example in the second metasurface layer; and forming a first opening through the first anti-reflection stack and the metasurface substrate down to the exposed portion of the metal trace.

According to an embodiment, forming the metal trace with the exposed portion is performed after forming the second metasurface layer and before removing the silicon wafer, and comprises: forming the metal trace in the second metasurface layer; forming a third metasurface layer of the metasurface substrate on the second metasurface layer to at least cover the metal trace; and forming a first opening through the first anti-reflection stack and the metasurface substrate down to the exposed portion of the metal trace.

According to an embodiment, the method further comprises forming a contact pad in contact with the exposed portion of the metal trace.

According to an embodiment, forming the metal trace with the exposed portion comprises forming a metal layer, for example a contact pad, on the first anti-reflection layer, the metal trace corresponding to at least a portion of the metal layer.

According to an embodiment, the first material is selectively etchable with respect to the third material, for example the first material is a silicon oxide and the third material is a silicon nitride.

According to an embodiment, the pillars are made of polycrystalline silicon, and the metasurface substrate is made of a silicon oxide.

According to an embodiment: the array of pillars comprise first pillars thoroughly crossing the first metasurface layer, and/or second pillars crossing a partial thickness of the first metasurface layer; and/or the pillars have cylindrical or conical shapes with main axes all parallel to one another; and/or the array of pillars comprise pillars having cross-sections of different widths or diameters.

According to an embodiment, the first anti-reflection stack and/or the second anti-reflection stack comprise a stack of dielectric layers with alternately high and low refractive indexes, for example silicon oxide or silicon oxynitride layers in alternance with silicon nitride layers.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A and FIG. 1B are simplified top and cross-section views of an example of an optical metasurface;

FIGS. 2A to 2L are perspective and cross-section views representing steps of a method of manufacturing an optical device 200 according to an embodiment;

FIG. 3A is a cross-section view representing an optical device obtained by the manufacturing method of FIGS. 2A to 2L;

FIG. 3B is a cross-section view representing a variant of the optical device of FIG. 3A;

FIG. 4 is a top view representing an example of a metal trace of an optical device; and

FIG. 5 is a top view representing another example of a metal trace of an optical device.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, all the components comprised in an optical device are not detailed, the embodiments being compatible with the components of usual optical devices, and all the optical devices that can be formed with a meta-structure are not detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, “upper” etc., or to qualifiers of orientation, such as “horizontal”, “vertical”, etc., reference is made to the orientation shown in the figures, or to an optical device as orientated during normal use.

Unless specified otherwise, the expressions “around”, “approximately”, “substantially” and “in the order of” signify within 10%, and preferably within 5%.

In the following disclosure, when reference is made to a lateral dimension, reference is made to a dimension in a plane parallel to the plane of the silicon wafer, and/or to the plane of stacking of the different layers of the optical device, and when reference is made to a thickness, reference is made to a dimension in a direction substantially perpendicular to the plane.

Optical devices, such as lenses, diffusers, filters, beam shapers, mirrors, etc., may incorporate an optical metasurface.

Optical metasurfaces are well known by those skilled in the art. An optical metasurface may be defined as a two-dimensional (2D) surface with distributed small structures arranged to interact with light in a particular manner. The small structures may consist of subwavelength, or “meta-atoms”, structures. For example, an optical metasurface, which also may be referred to as an optical metastructure, may be a surface with a distributed array of nanostructures. The nanostructures may, individually or collectively, interact with light waves. For example, the nanostructures or other meta-atoms may change a local amplitude, a local phase, or both, of an incoming light wave.

When the meta-atoms, for example the nanostructures, of an optical metasurface are in a particular arrangement, the optical metasurface may form, or be part of, an optical device, such as a lens, a filter, a beam shaper, a diffuser, etc. In some instances, optical metasurfaces may perform optical functions that are traditionally performed by refractive and/or diffractive optical elements.

In the following disclosure, an optical metasurface, or an optical metastructure, may be referred to as a metasurface.

In the following disclosure, unless indicated otherwise, when reference is made to a transparent layer or element, this includes a layer or an element made of a material which is relatively transparent to light at the wavelengths used, or at the wavelengths of interest, for example has a transmission rate of 90 percent or more for these wavelengths.

In the following disclosure, unless indicated otherwise, when reference is made to a glass, or a glass substrate, this includes an element made of a material which is relatively transparent to light at the wavelengths used, or at the wavelengths of interest, for example has a transmission rate of 90 percent or more for these wavelengths. This includes, without being limited to, a glass material or plastic material.

In the following disclosure, unless indicated otherwise, when reference is made to a filter, reference is made to an optical filter.

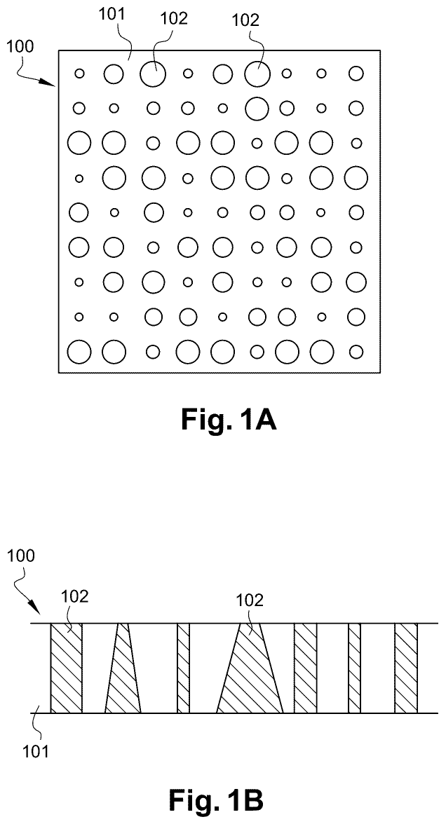

FIG. 1A and FIG. 1B are simplified top and cross-section views of an example of an optical metasurface 100.

FIG. 1A illustrates a portion of the metasurface 100, and FIG. 1B illustrates a portion of a row or of a column of pillars of the metasurface 100.

The metasurface 100 is a structure formed of a substrate 101, extending through which are formed pillars 102. Pillars 102 cross the substrate 101 and are generally made of a material different from the material of the substrate. According to an embodiment, the material of pillars 102 has a different optical index than the material of the substrate 101. According to an example, pillars 102 thoroughly cross the substrate 101. According to another example, pillars 102 cross a portion of the substrate 101 and their ends are covered with a portion of the substrate or by one or a plurality of layers of different materials, such as, for example, etch stop layers and/or anti-reflection layers. The substrate 101 may, for example, have a thickness in the range from 10 nm to 10 μm.

According to an example, the material of substrate 101 may be selected from the non-exhaustive group comprising: quartz, a compound comprising quartz, silicon, a compound comprising silicon, silicon oxide, silicon nitride, a compound of silicon and carbon, metal oxides of silicon, glass, a compound comprising glass, a compound of aluminum, such as a compound of aluminum and arsenic, and a compound of gallium, such as a compound of gallium and arsenic.

According to an example, the material of pillars 102 may be selected from the non-exhaustive group comprising: quartz, a compound comprising quartz, silicon, a compound comprising silicon, silicon oxide, silicon nitride, a compound of silicon and carbon, metal oxides of silicon, glass, a compound comprising glass, a compound of aluminum, such as a compound of aluminum and arsenic, and a compound of gallium, such as a compound of gallium and arsenic.

Pillars 102 are generally arranged in the form of an array, that is, in rows and in columns with a regular interval. According to a variant, pillars 102 are arranged with a spatial arrangement where they are spaced apart with an irregular interval.

Pillars 102 are generally of cylindrical or conical shape with main axes all parallel to one another and having a cross-section that may have different diameters and different shapes. More particularly, reference is here made to a diameter of a pillar 102 as the diameter of a fictive circle having the shape of the cross-section of pillar 102, that is, the greatest width of the shape of the cross-section of pillar 102, inscribed therein. According to an example, the diameter of a pillar 102 may be in the range from 50 nm to 4 μm. The cross-section of pillars 102 may have different shapes. Further, reference is made, in the following description, to the shape of a pillar 102 as the shape of the cross-section of a pillar 102.

An optical metasurface may be used to form any types of optical devices, such as converging lenses, diverging lenses, optical filters, diffusers, etc. To obtain these different optical properties, it may be necessary to use pillars having different diameters and/or shapes in the same structure, and to use an appropriate distribution of these different pillars. According to an example, a random distribution of pillars of different diameters may enable to create a metastructure with a diffuser function, while a non-random distribution, for example, with a diameter of pillars 102 decreasing or increasing towards a central point of the metastructure, may enable to form a converging or diverging lens function.

An optical metasurface may be obtained using an electron-beam lithography technique. However, this technique is generally not compatible with mass production.

An optical metasurface may be obtained using a nano-imprint lithography technique. Generally, this technique consists in forming a layer of imprint resist on a substrate, and then pressing a mold having predefined topological patterns onto the substrate with the imprint resist between, thus reporting the patterns in the imprint resist, and then removing the mold. The patterned imprint resist can then serve as an etching mask to etch corresponding patterns in the substrate. One drawback of the nano-imprint lithography technique is the use of the mold, which requires to be changed when the patterns in the imprint resist needs to be changed. Therefore, this technique is not easily adaptable to different schemes of patterns.

In order to overcome the previously described drawbacks, manufacturing an optical metasurface may use well-known techniques and equipment used in the field of microelectronics, for example, the use of etching, deposition, masking and/or lithography used for the manufacturing of microelectronic components. For example, techniques and equipment for manufacturing microelectronic components on a silicon substrate may be used by forming a structure comprising layers, including the metasurface, on the silicon substrate acting as a manufacturing support, by transferring the obtained structure onto a transparent substrate such as a glass substrate, then eliminating the silicon substrate.

One benefit of using these techniques and equipment for the manufacturing of optical metasurfaces is that it uses generic materials, which lowers the production costs, and that the manufacturing is scalable to very high volumes, and thus, is compatible with mass production. In addition, microelectronic techniques allow forming very small patterns, such as nanometric patterns, for example using high precision toolsets such as dry or immersion lithography, to obtain effective metasurfaces, and to form optical devices with high yield.

An optical device incorporating an optical metasurface may be integrated into an optical sensor module that houses one or more optoelectronic devices, for example at least a light emitting device, and generally also a light sensing device. The metasurface can be used, for example, to modify one or more characteristics, such as phase, amplitude, angle, of an emitted or incoming light wave as it passes through the metasurface. For example, the optical device with the metasurface may be positioned over the light emitting device and the metasurface may function as a diffuser suitable for reducing to some extent the intensity of a light beam emitted by the light emitting device, for example for safety reasons, such as protecting a user. However, if the optical device is detached, broken, or otherwise removed from over the light-emitting device, the light-emitting device will no longer be covered, exposing the user to the full intensity of the light beam. In order to address this safety issue, the optical device may include a metal trace, or safety trace. Generally, the metal trace is arranged to be electrically coupled to a voltage rail, and the optical sensor module may include a detection circuit coupled to the metal trace, and configured to detect whether the metal trace is coupled to, or disconnected from, the voltage rail. If a disconnection is detected, the light emitting device can be cut off.

More generally, the optical device incorporating a metasurface may include a safety feature, such as a metal trace, configured to ensure user security and/or optical device integrity.

The previous methods, such as the previous methods using microelectronic techniques, generally do not offer an integrated solution for fabricating metasurfaces integrated in optical devices. For example, the metasurfaces may be manufactured by one manufacturer and assembled to optical devices by another manufacturer or assembler, and this may raise assembly problems. For example, the assembly of metasurfaces in optical devices may be subjected to assembly complexity and constraints, such as stress during a thermal treatment, due to different materials to be assembled, which may raise a problem of reliability during the assembly.

The previous methods, such as the previous methods using microelectronic techniques, generally do not provide safety features, and for example do not provide an electrical connection of these safety features. For example, if the metasurfaces are manufactured by one manufacturer and assembled to optical devices by another manufacturer or assembler, this may raise a problem of electrically connecting the safety features.

The inventors propose a method for manufacturing optical devices including metasurfaces, which makes it possible to overcome all or part of the aforementioned drawbacks, in particular to offer an integrated solution for fabricating metasurfaces integrated in optical devices, this solution being preferably easily and low-costly adaptable to different schemes of metasurfaces. It would be desirable that this integrated solution provides safety features for user protection and/or for optical device integrity, and an electrical connection for such safety features.

Embodiments of methods for manufacturing optical devices including metasurfaces, and corresponding optical devices, will be described below. These embodiments are non-limiting and various variants will appear to the person skilled in the art from the indications of the present description.

For the sake of simplification, the following description will be made in the case where the substrate of the metasurface (metasurface substrate) is made of a silicon oxide, such as a silicon dioxide (SiO₂), and the pillars in the substrate are made of polycrystalline silicon (polysilicon). However, the person skilled in the art will understand that other materials may be used according to the intended application, for example according to the optical device and to the intended wavelength ranges. The material of the pillars is preferably a material with adequate refractive index contrast with the metasurface substrate, for example a hydrogenated amorphous silicon (a-Si: H).

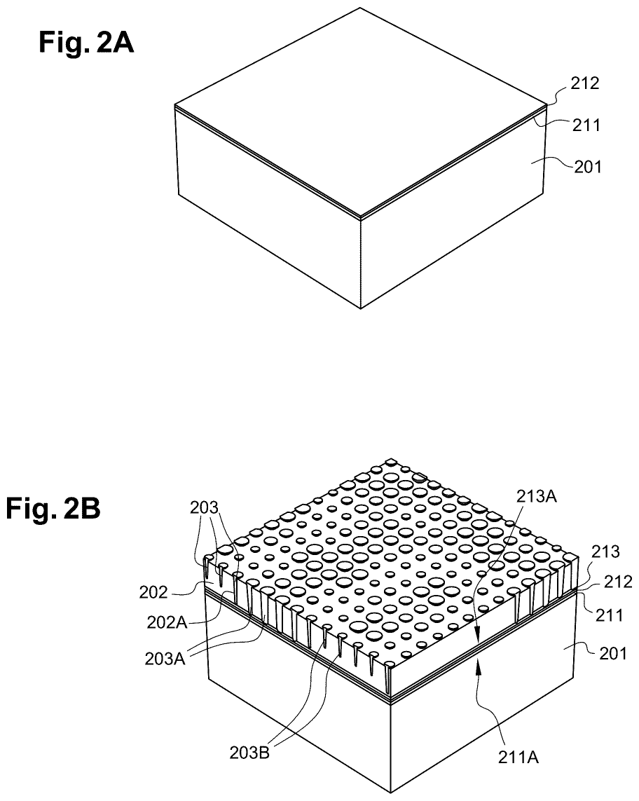

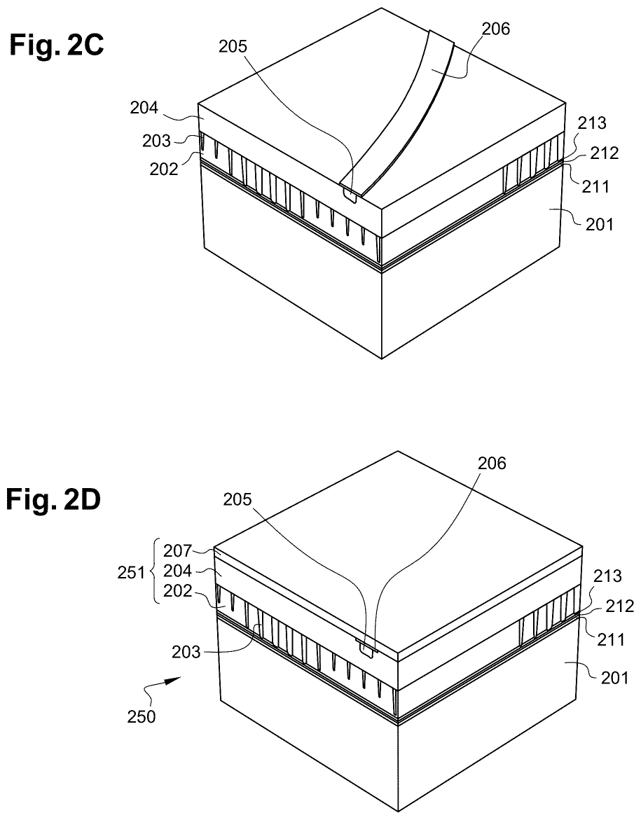

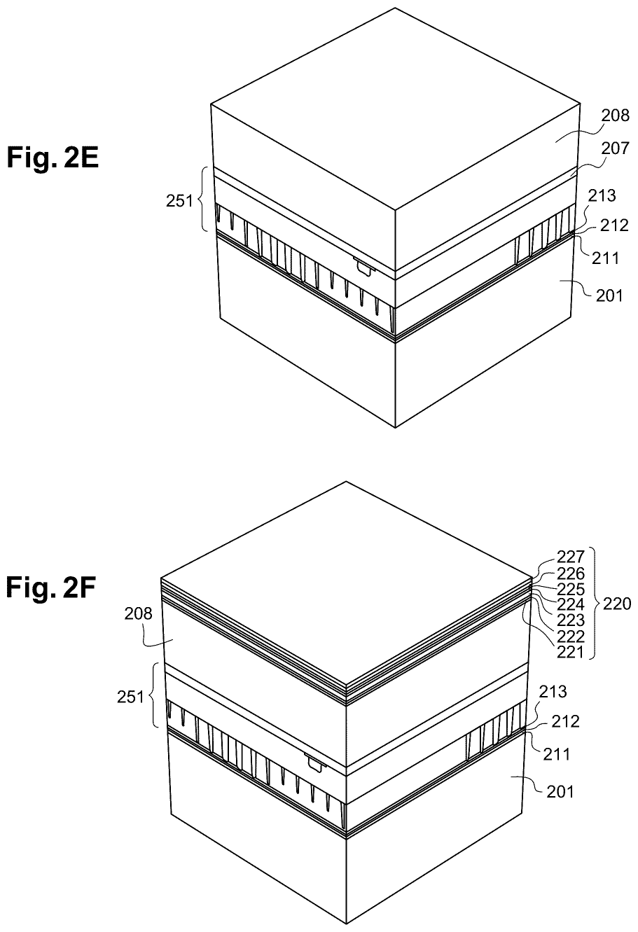

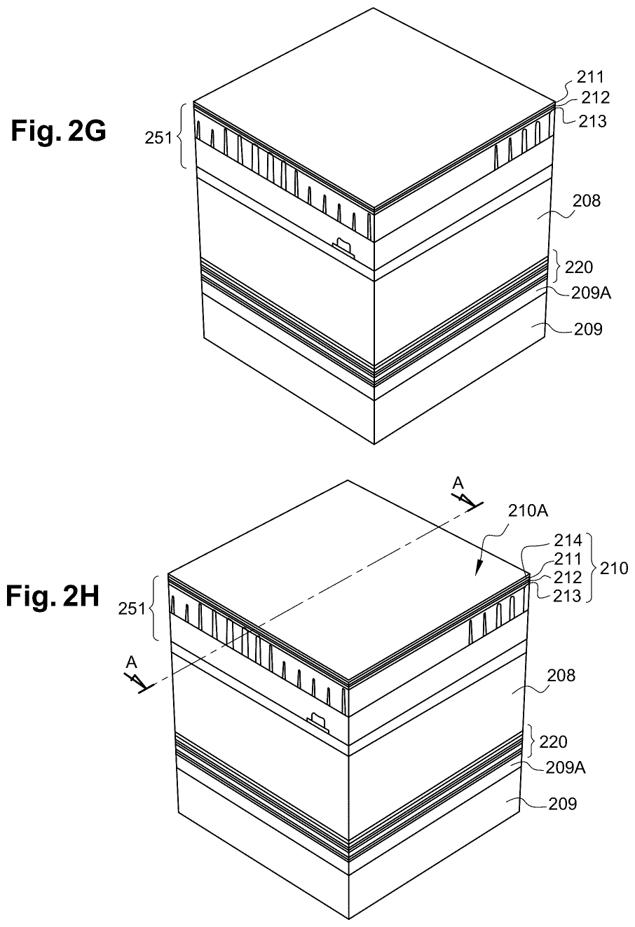

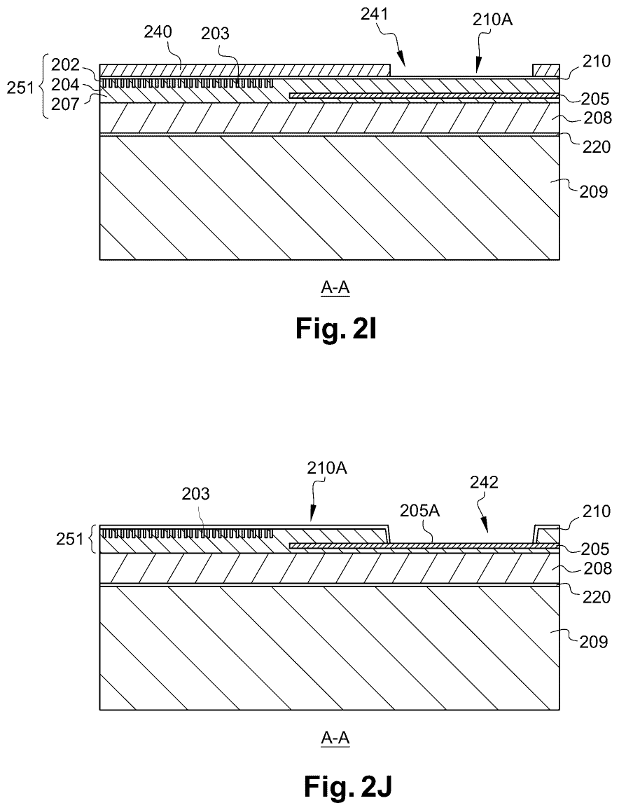

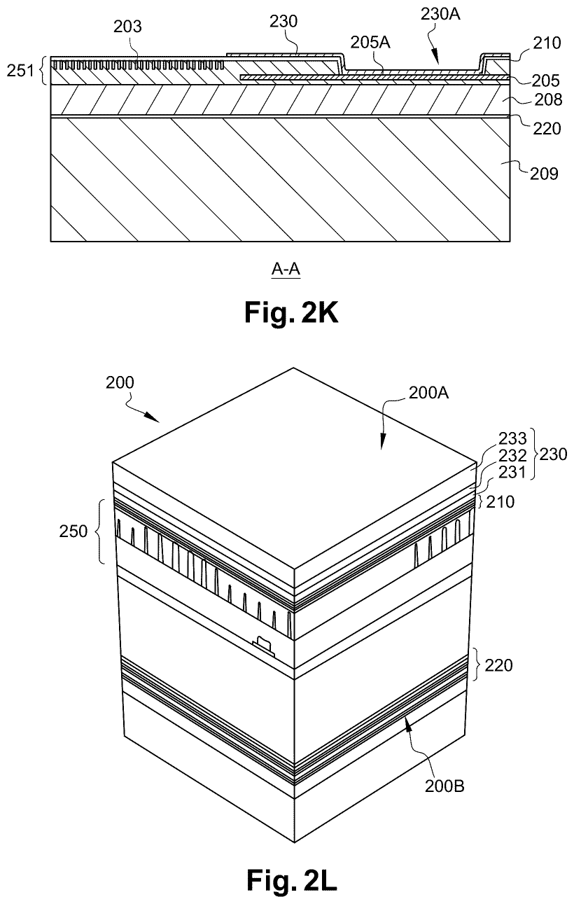

FIGS. 2A to 2L are perspective and cross-section views representing steps of a method of manufacturing an optical device 200 according to an embodiment.

In these figures, only a portion of the silicon wafer is represented on the understanding that, in practice, multiple optical devices are generally formed simultaneously on the silicon wafer, these optical devices then being individually separated by cutting up the silicon wafer, for example by sawing.

FIG. 2A is a perspective view representing a starting structure comprising a silicon wafer 201 which acts as a carrier or support for manufacturing the optical device. A layer 211 of a dielectric material is formed on the silicon wafer 201, and a layer 212 of a dielectric material is formed on layer 211.

Layer 211 preferably corresponds to an etch stop layer, for the subsequent step of removal of the silicon wafer 201, described hereafter in relation with FIG. 2G. Therefore, the dielectric material of layer 211 is preferably selected accordingly with respect to silicon, such as being not removed when the silicon is removed. The dielectric material of layer 211 is a transparent material, and is for example selectively etchable with respect to the silicon. The dielectric material of layer 211 is, for example, a silicon nitride (SiN).

Layer 211 may be formed using a chemical vapor deposition (CVD) technique, for example low pressure chemical vapor deposition (LPCVD) or plasma enhanced chemical vapor deposition (PECVD).

The dielectric material of layer 212 is preferably different from the dielectric material of layer 211. The dielectric material of layer 212 is a transparent material, and is preferably a material with an adequate refractive index contrast with layer 211, for example a silicon oxide, such as a silicon dioxide (SiO₂). Layer 212 may be formed using a CVD technique, for example PECVD.

Additional layers could be formed on layers 211, 212, or between layer 211 and layer 212, for example to improve the optical performances of the optical device 200. These additional layers would preferably alternate between materials of different refractive indexes, for example to maximize optical transmission at this interface.

FIG. 2B is a perspective view representing a structure obtained after: forming a layer 213 of a dielectric material on layer 212; forming a layer 202 (first metasurface layer) of a dielectric material (first material) on layer 213; and patterning layer 202 to form openings 202A (second openings) through layer 202; and filling the openings 202A with a filling material which is preferably different from the dielectric material of layer 202, to form an array of pillars 203.

The dielectric material of layer 213 (third material) is preferably different from the dielectric material of layer 212, but may be the same as the dielectric material of layer 211. The dielectric material of layer 213 is a transparent material, and is preferably a material with an adequate refractive index contrast with layer 212, for example a silicon nitride. Layer 213 may be formed using a CVD technique, for example LPCVD or PECVD.

Layer 213 preferably correspond to an etch stop layer, for the etching of layer 202 to form the openings 202A. Therefore, the dielectric material of layer 202 (first material) is preferably different from the dielectric material of layer 213 (third material), and preferably selectively etchable with respect to the third material, for example to avoid etching layer 213 when layer 202 is etched.

The dielectric material of layer 202 (first material) is preferably a transparent material, and may be the same as the dielectric material of layer 212, for example a silicon oxide, or may be different, for example a silicon nitride, if the dielectric material of layer 213 is not a silicon nitride. Layer 202 may be formed using a CVD technique, for example PECVD.

The patterning of layer 202 comprises well-known techniques in the field of microelectronics, which are not represented, such as (photo) lithography, etching, deposition, and planarization, for example: forming a lithography mask on layer 202, the lithography mask comprising openings having shapes and lateral dimensions corresponding to the shapes and lateral dimensions of the pillars to be formed; etching layer 202 through the openings of the lithography mask to form the openings 202A in layer 202, and then removing the lithography mask; depositing a filling layer of the filling material to at least fill the openings 202A; and optionally, removing the possible part of the filling layer remaining on layer 202 using a planarization method, such as a chemical mechanical polishing (CMP).

The lithographic mask defines the shapes of the upper faces of the pillars 203. For example, in order to manufacture cylindrical or conical pillars, the lithographic mask may comprise a grid of circular openings.

In the represented example, the array of pillars 203 comprise first pillars 203A thoroughly crossing layer 202, and second pillars 203B crossing a partial thickness of layer 202. In the represented example, the pillars 203 have cylindrical or conical shapes with main axes all parallel to one another and a cross-section that has different diameters. This example is not limitative and other configurations can be encompassed by those skilled in the art.

The material (second material) of the pillars 203 and the dielectric material (first material) of layer 202 are different, and have preferably different refractive indexes. For example, the material of the pillars 203 may be a polycrystalline silicon, and the dielectric material of layer 202 a silicon oxide.

The filling step may be followed by an anneal step, for example if the filling material is an amorphous silicon, in order to form pillars 203 in polycrystalline silicon. Therefore, the filling material may be different from the final material of the pillars (second material).

The pillars 203 may be flush with the upper face of layer 202, or may extend slightly above the upper face of layer 202.

Layers 211, 212, 213 form a first stack of a first anti-reflection stack 210 (shown in FIG. 2H), or anti-reflection coating. The first stack has an upper face (first face) 213A corresponding to an upper face (first face) of layer 213 in contact with layer 202, and a lower face (second face) 211A corresponding to the lower face of layer 211 in contact with the silicon wafer 201.

FIG. 2C is a perspective view representing a structure obtained after: forming a layer 204 (second metasurface layer) of a dielectric material on the patterned layer 202 to at least cover the upper faces of the pillars 203; forming a metal trace 205 in layer 204, preferably from the upper face of layer 204; and covering the metal trace 205 by a covering layer 206 of a dielectric material preferably different from the dielectric material of layer 204.

The dielectric material of layer 204 may be the same as the dielectric material of layer 202, that is the first material, for example a silicon oxide, or may be a different material with the same refractive index as layer 202. Layer 204 may be formed using a CVD technique, for example PECVD.

The dielectric material of the covering layer 206 may be the same as the dielectric material of layer 211 and/or layer 213, that is the third material, for example a silicon nitride, or may be different. The dielectric material of the covering layer 206 is preferably a material capable of forming a diffusion barrier for the metal of the metal trace 205, for example for copper. Since the surface of the metal trace has a limited footprint, the dielectric material of the covering layer 206 is not necessarily transparent. The covering layer 206 may be formed using a CVD technique, for example LPCVD or PECVD.

The covering layer 206 preferably does not cover the entire upper face of layer 204, for example the covering layer 206 forms a band that covers the metal trace 205 and extends on either side of this metal trace.

The material of the metal trace 205 is, for example, copper (Cu), or any other conductive material, not necessarily transparent.

The metal trace 205 may be obtained using well-known techniques in the field of microelectronics, which are not represented, such a damascene process, that is: forming a lithography mask on layer 204, the lithography mask comprising an opening having a shape and lateral dimensions corresponding to the shape and lateral dimensions of the metal trace to be formed; etching layer 204 through the opening of the lithography mask to form an opening (or trench) in/through layer 204, and then removing the lithography mask; depositing a metal layer to at least fill the opening of layer 204; and optionally, removing the possible part of the metal layer remaining on layer 204 using a planarization method, such as a chemical mechanical polishing (CMP).

FIG. 2D is a perspective view representing a structure obtained after forming a layer 207 (third metasurface layer) of a dielectric material on layer 204 and on the covered metal trace 205.

The dielectric material of layer 207 is preferably the same as the dielectric material of layer 204, and/or may be the same as the dielectric material of layer 202, that is the first material, for example a silicon oxide. Layer 207 may be formed using a CVD technique, for example PECVD.

Layer 207 may be referred to as a bonding interface layer for the subsequent assembly with a glass substrate 208. The bonding interface layer 207 may be thinned and/or planarized before the subsequent assembly with the glass substrate 208.

Layers 202, 204, 207 may be referred to as respectively first, second and third metasurface layers forming a metasurface substrate 251, and the metasurface substrate 251 with the pillars 203 may be referred to as a metasurface 250, or metastructure.

FIG. 2E is a perspective view representing a structure obtained after forming a glass substrate 208 on layer 207.

For example, the glass substrate 208 is bonded by molecular bonding to the bonding interface layer 207.

The glass substrate 208 may be planarized and/or thinned down to a thickness less than or equal to around 210 μm.

In an advantageous embodiment, the material of the glass substrate 208 and the dielectric material of layer 207 are of similar materials and/or have preferably identical refractive indexes, which makes it possible to limit or even eliminate the parasitic reflections at the interface between the glass substrate 208 and layer 207.

FIG. 2F is a perspective view representing a structure obtained after forming a second anti-reflection stack 220 on the glass substrate 208.

The second anti-reflection stack may be referred to as a back-side anti-reflection stack, as it is dedicated to be positioned at the back face 200B (second face) of the future optical device 200 (shown in FIG. 2L).

The second anti-reflection stack 220 can be a stack of dielectric layers with alternately high and low refractive indexes, for example silicon oxide or silicon oxynitride (SiON) layers in alternance with silicon nitride (SiN) layers.

As a non-limiting example, the second anti-reflection stack 220 may comprise: a first anti-reflection (AR) layer 221 of silicon oxide or silicon oxynitride on the glass substrate 208; a second anti-reflection (AR) layer 222 of silicon nitride on the first AR layer 221; a third anti-reflection (AR) layer 223 of silicon oxide or silicon oxynitride on the second AR layer 222; a fourth anti-reflection (AR) layer 224 of silicon nitride on the third AR layer 223; a fifth anti-reflection (AR) layer 225 of silicon oxide or silicon oxynitride on the fourth AR layer 224; a sixth anti-reflection (AR) layer 226 of silicon nitride on the fifth AR layer 225; and a seventh anti-reflection (AR) layer 227 of silicon oxide or silicon oxynitride on the sixth AR layer 226.

The anti-reflection layers may be formed using a CVD technique, for example PECVD.

The second anti-reflection stack 220 may allow maximizing optical transmission, for example by minimizing Fresnel reflection from the glass substrate 208.

Other configurations of the second anti-reflection stack 220, such as other number of layers, and/or other dielectric materials and/or material combination, and/or thicknesses, can be encompassed by those skilled in the art, for example to maximize the optical transmission in the wavelengths of interest, over the range of appropriate angles of incidence and suitable for the available tools for manufacturing.

FIG. 2G is a perspective view representing a structure obtained after flipping the structure of FIG. 2F and removing the silicon wafer 201.

The silicon wafer 201 may be removed by grinding, for example grinding a main part of the thickness of this silicon wafer and then polishing the remaining part of this silicon wafer up to layer 211 which may be selected to stop the polishing.

Optionally, a temporary silicon carrier 209 may be assembled, or bonded, to the second anti-reflection stack 220, before, or after, flipping the structure of FIG. 2F, and preferably before removing the silicon wafer 201. The temporary silicon carrier 209 may be used to strengthen the structure when the silicon wafer 201 is removed. For example, the temporary silicon carrier 209 is bonded to the second anti-reflection stack 220 using a dry adhesive film 209A having a thickness of for example 65 μm.

FIG. 2H is a perspective view representing a structure obtained after forming a layer 214 of a dielectric material on layer 211.

The dielectric material of layer 214 is preferably different from the dielectric material of layer 211, and is for example silicon dioxide, or silicon oxynitride. Layer 214 may be formed using a CVD technique, and may be a low temperature oxide (LTO) oxide.

Layer 214 may form, with the first stack of layers 211, 212, 213, the first anti-reflection stack 210. Layers 214, 211, 212, 213 may be referred to as respectively the first anti-reflection layer, the second anti-reflection layer, the third anti-reflection layer, and the fourth anti-reflection layer of the first anti-reflection stack 210. The upper face 210A (first face) of the first anti-reflection stack 210 corresponds to the upper face of layer 214.

Instead of a layer 214, it could be a stack of layers (second stack).

The first anti-reflection stack 210 may be referred to as a front-side anti-reflection stack, as it is dedicated to be positioned at the front face 200A (first face) of the future optical device 200 (shown in FIG. 2L).

Other configurations of the first anti-reflection stack 210, such as other number of layers, and/or other dielectric materials and/or material combinations, and/or thicknesses, can be encompassed by those skilled in the art, for example to maximize the optical transmission in the wavelengths of interest, over the range of appropriate angles of incidence and suitable for the available tools for manufacturing. The first anti-reflection stack is preferably a stack of dielectric layers with alternately high and low refractive indexes.

The first anti-reflection stack 210 may be configured to correct an angle of incidence of light beams reaching the array of pillars. For example, the first anti-reflection stack 210 may be configured to correct the initial angle of incidence of light beams relative to the normal of the front face 200A of the optical device 200 so as to rectify the initial incident light rays so that the angle of the incident rays on the array of pillars is as close as possible to the normal.

FIGS. 21, 2J and 2K are cross-section views in the AA direction shown in FIG. 2H representing exemplary steps for electrically connecting the metal trace 205 which is embedded in layers 202, 204, 207, in other words in the metasurface substrate 251.

FIG. 2I represents a structure obtained after depositing a resist mask 240 on the upper face 210A (first face) of the first anti-reflection stack 210. The resist mask 240 preferably covers the array of pillars 203, and has an opening 241 which is positioned above the metal trace 205 away from the array of pillars 203.

FIG. 2J represents a structure obtained after etching the first anti-reflection stack 210 and layers 202, 204, 207, that is the metasurface substrate 251, through the opening 241 of the resist mask 240 down to the metal trace 205, in order to form an opening 242 (first opening) through the first anti-reflection stack 210 and the metasurface substrate 251, and to access the metal trace 205. The resist mask 240 is then stripped. The metal trace 205 thus comprises a portion 205A which is exposed at the upper face 210A of the first anti-reflection stack 210.

FIG. 2K represents a structure obtained after depositing a contact pad 230, or over pad metallization, on the first anti-reflection stack 210 and in the opening 242, in order to connect the exposed portion 205A of the metal trace 205. The contact pad 230 follows the shape of the upper face of the structure of FIG. 2J, and thus includes a recess 230A which substantially corresponds to the opening 242.

FIG. 2L is a perspective view representing the optical device 200 obtained after the contact pad 230 is formed, with the temporary silicon carrier 209 not removed yet (the final optical device does not comprise this temporary silicon carrier). For the sake of simplification, FIG. 2L does not represent the recess 230A of the contact pad 230 that is shown in the cross-section view of FIG. 2K.

The contact pad 230 may comprise a plurality of layers, for example: a first metal layer 231, for example a titanium (Ti) layer on the first anti-reflection stack 210: the first metal layer 231 preferably acts as an adhesion interface layer with the first anti-reflection stack 210, for example with layer 214 which may be a silicon dioxide or oxynitride layer, and/or as a metal diffusion barrier; a second metal layer 232, for example a layer of a titanium tungsten alloy (TiW), on the first metal layer 231: the second metal layer 232 preferably also acts as an adhesion interface layer and/or as a metal diffusion barrier; a third metal layer 233 to form an electrical contact, for example a gold layer, on the second metal layer 232.

The described manufacturing method shows advantages of having such integrated method, which is adapted to form an optical device by forming a metasurface, positioning a glass substrate on the metasurface and by forming the front-side and back-side anti-reflection stacks respectively on the metasurface and on the glass substrate, using microelectronic techniques and equipment. The integrated manufacturing method is configured to form precise patterns and thus a high resolution optical device, is adaptable to different schemes of metasurfaces, and is cost-saving. In addition, the integrated manufacturing method allows forming an electrical contact through the first anti-reflection stack, for example to connect a safety trace in the metasurface.

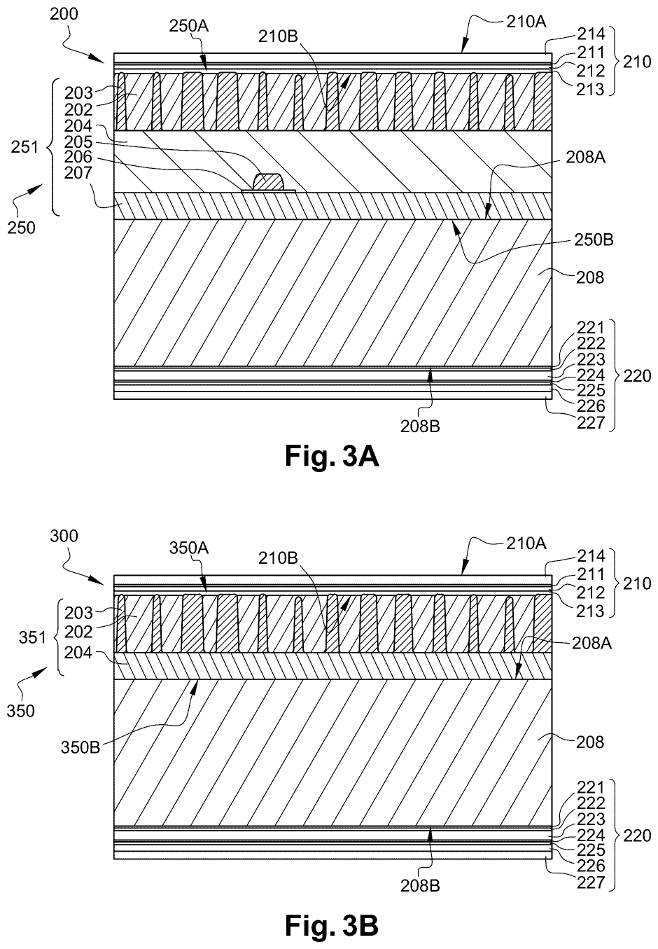

FIG. 3A is a cross-section view representing an optical device 200 obtained by the manufacturing method of FIGS. 2A to 2L, after the temporary silicon carrier 209 is removed. FIG. 3B is a cross-section view representing a variant of the optical device of FIG. 3A.

For the sake of simplification, the contact pad 230 is not represented in FIGS. 3A and 3B.

The optical device 200 of FIG. 3A corresponds substantially to the optical device of FIG. 2L, without the contact pad 230 being represented, and without the temporary silicon carrier 209 which has been removed.

The optical device 200 therefore comprises: a metasurface 250 having an upper face 250A (first face) and a lower face 250B (second face); a first anti-reflection stack 210 covering the upper face 250A of the metasurface 250, the first anti-reflection stack having an upper face 210A (first face) opposite a lower face 210B (second face) which faces the metasurface; a glass substrate 208 having an upper face 208A (first face) covered by the metasurface 250 and a lower face 208B (second face) opposite the first face; a second anti-reflection stack 220 covered by the lower face 208B of the glass substrate 208.

The metasurface 250 includes an array of pillars 203, as well as a metal trace 205, embedded in the metasurface substrate 251. Although not shown in FIG. 3A, but shown in FIG. 2J, a portion 205A of the metal trace 205 is exposed at the upper face 210A of the first anti-reflection stack 210 by means of an opening 242 in the first anti-reflection stack 210 and the metasurface substrate 251 extending down to that portion of the metal trace.

A non-limiting example of the materials and of thickness ranges of the different layers and elements of the optical device 200 of FIG. 3A is given in the following table 1:

TABLE 1

| Layer or element | Example | Thickness | |
|---|---|---|---|
| reference | of material | ranges | |
| layer 214 | SiO₂ | 110-150 | nm |
| layer 211 | SiN | 10-20 | nm |
| layer 212 | SiO₂ | 40-60 | nm |
| layer 213 | SiN | 45-65 | nm |
| pillars 203 | polysilicon | 550-850 nm (higher | |
| | | thickness) | |
| metasurface | SiO₂ | 1-2 | μm |
| substrate 251 | | | |
| metal trace 205 | Cu | 150-250 | nm |
| glass substrate 210 | glass | 150-250 | μm |
| layer 221 | SiON | 15-30 | nm |
| layer 222 | SiN | 20-35 | nm |
| layer 223 | SiON | 80-130 | nm |
| layer 224 | SiN | 15-25 | nm |
| layer 225 | SiON | 25-45 | nm |
| layer 226 | SiN | 60-90 | nm |
| layer 227 | SiON | 70-110 | nm |

The optical device 300 of FIG. 3B differs from the optical device of FIG. 3A in that the metasurface 350 does not include a metal trace, and that the metasurface substrate 351 does not comprise the third metasurface layer, that is layer 207 of FIG. 3A. Therefore, the metasurface substrate 351 of the optical device 300 of FIG. 3B has a lower thickness than the metasurface substrate 251 of the optical device 200 of FIG. 3A.

A non-limiting example of the materials and of thickness ranges of the different layers and elements of the optical device 300 of FIG. 3B is given in the following table 2:

TABLE 2

| Layer or element | Example | Thickness | |
|---|---|---|---|
| reference | of material | ranges | |
| layer 214 | SiO₂ | 110-150 | nm |
| layer 211 | SiN | 10-20 | nm |
| layer 212 | SiO₂ | 40-60 | nm |
| layer 213 | SiN | 45-65 | nm |
| pillars 203 | polysilicon | 550-850 nm (higher | |
| | | thickness) | |
| metasurface | SiO₂ | 0.5-1.5 | μm |
| substrate 351 | | | |
| glass substrate 210 | glass | 150-250 | μm |
| layer 221 | SiON | 15-30 | nm |
| layer 222 | SiN | 20-35 | nm |
| layer 223 | SiON | 80-130 | nm |
| layer 224 | SiN | 15-25 | nm |
| layer 225 | SiON | 25-45 | nm |
| layer 226 | SiN | 60-90 | nm |
| layer 227 | SiON | 70-110 | nm |

The metasurface 250 of FIGS. 2D to 2L and of FIG. 3A includes, for example embeds, the metal trace 205 which has a portion 205A which is exposed at the upper face 210A of the first anti-reflection stack 210.

In a variant, the metal trace may not be included or embedded in the metasurface 350, as in the example of FIG. 3B. In this variant, the metal trace may be formed by at least a portion of a contact pad, such as the contact pad 230 of FIG. 2L, which is exposed at the front face of the optical device, that is at the upper face of the first anti-reflection stack. The metal trace may be formed, for example, by at least a portion of a gold layer corresponding to an upper layer of the contact pad, such as the gold layer 233 of FIG. 2L. The contact pad, for example the gold layer, may be patterned to form the metal trace.

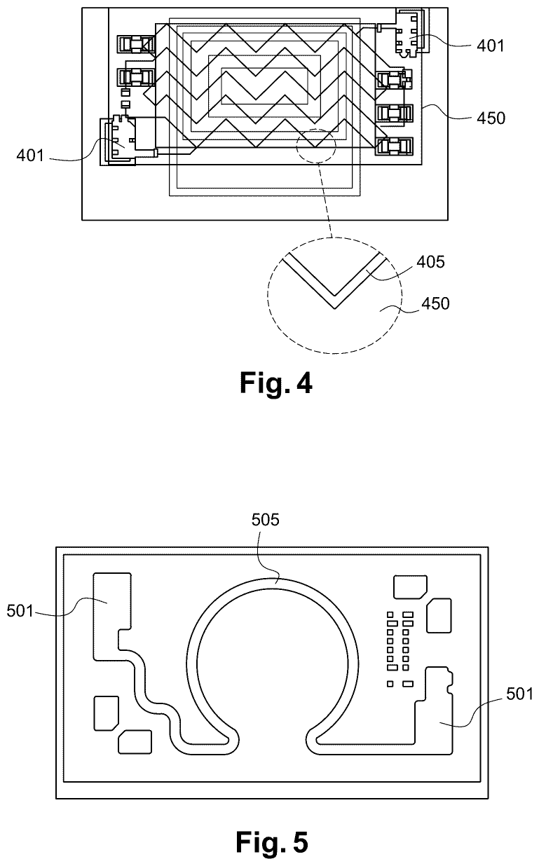

FIG. 4 is a top view representing an example of a metal trace 405 of an optical device according to an embodiment. In this example, the metal trace 405 is embedded in the metasurface 450. The optical device is, for example, the optical device 200 of FIG. 2L and/or FIG. 3A.

The metal trace 405 of FIG. 4 has a zig-zag shape, and is connected at its ends to conductive pads 401. The conductive pads may be exposed at the front face of the optical device, that is at the upper face of the first anti-reflection stack. This shape is a non-limiting one and other shapes can be encompassed by those skilled in the art.

FIG. 5 is a top view representing another example of a metal trace 505 of an optical device according to an embodiment. In this example, the metal trace 505 is not included or embedded in the metasurface. The optical device is, for example, the optical device 300 of FIG. 3B.

The metal trace 505 is formed by a metal layer exposed at the front face of the optical device, that is at the upper face of the first anti-reflection stack, for example a gold layer of a contact pad, which is patterned to form the metal trace. The metal trace 505 of FIG. 5 has an omega shape. This shape is a non-limiting one and other shapes can be encompassed by those skilled in the art.

The metal trace 505 is connected at its ends to conductive pads 501.

More generally, and wherever it is positioned, the metal trace preferably comprises conductive contacts, such as conductive pads, which are configured to be at a fixed voltage, for example electrically coupled, or connected, to a voltage rail.

A detection circuit may be coupled to the metal trace, the detection circuit being configured to detect whether the metal trace is coupled to, or disconnected from, the voltage rail. If a disconnection is detected, an action such as cutting off a light emitting device which is covered by the optical device can be performed.

The optical device with the metasurface may be integrated to an optical sensor module housing one or more optoelectronic devices, for example at least a light emitting device, and generally also a light sensing device. The metasurface of the optical device can be used, for example, to modify one or more characteristics, such as phase, amplitude, angle, of an emitted or incoming light wave as it passes through the metasurface.

The optical device with the metasurface may be placed over the light emitting device. For example, the metasurface may function as a diffuser suitable for reducing to some extent the intensity of a light beam emitted by the light emitting device, and the metal trace may be used to detect whether the optical device is detached, broken, or otherwise removed from over the light-emitting device, and, if so, the light emitting device can be cut off.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. An optical device, comprising:
a metasurface comprising a metasurface substrate having at least a first metasurface layer made of a first material, and an array of pillars extending through the first metasurface layer, the pillars being made of a second material different from the first material, the metasurface having a first face and a second face opposite the first face;
a first anti-reflection stack having a third face and a fourth face opposite the third face, wherein the fourth face of the first anti-reflection stack is positioned over the first face of the metasurface; and
a metal trace having a portion which is exposed at the third face of the first anti-reflection stack.

2. The optical device according to claim 1, wherein the first metasurface layer extends at the first face of the metasurface.

3. The optical device according to claim 1, wherein the metal trace is included in the metasurface substrate, and further comprising a first opening extending through the first anti-reflection stack and the metasurface substrate down to the portion of the metal trace which is exposed.

4. The optical device according to claim 3, wherein the metal trace is embedded in a second metasurface layer of the metasurface substrate in contact with the first metasurface layer, the metasurface substrate further comprising a third metasurface layer in contact with the second metasurface layer and covering the metal trace, the second metasurface layer being between the first metasurface layer and the third metasurface layer.

5. The optical device according to claim 1, wherein the metal trace is positioned over the third face of the first anti-reflection stack.

6. The optical device according to claim 5, wherein the metal trace corresponds to at least a portion of a contact pad.

7. The optical device according to claim 1, further comprising a transparent substrate, the second face of the metasurface being over a fifth face of the transparent substrate.

8. The optical device according to claim 7, wherein transparent substrate is a glass substrate.

9. The optical device according to claim 7, further comprising a second anti-reflection layer, and wherein a sixth face of the transparent substrate which is opposite the fifth face of said transparent substrate is over said second anti-reflection layer.

10. The optical device according to claim 1, wherein the first anti-reflection stack comprises a stack of dielectric layers with alternately high and low refractive indexes.

11. The optical device according to claim 1, wherein the first anti-reflection stack comprises a stack of dielectric layers comprises silicon oxide or silicon oxynitride layers in alternance with silicon nitride layers.

12. The optical device according to claim 1, wherein the pillars are made of polycrystalline silicon, and the metasurface substrate is made of a silicon oxide.

13. The optical device according to claim 1, wherein the array of pillars comprise one or more of: first pillars thoroughly crossing the first metasurface layer; and second pillars crossing a partial thickness of the first metasurface layer.

14. The optical device according to claim 1, wherein the array of pillars comprise pillars having one or more of cylindrical or conical shapes with main axes all parallel to one another.

15. The optical device according to claim 1, wherein the array of pillars comprise pillars having one or more of: cross-sections of different widths and cross-sections of different diameters.

16. A method of manufacturing of an optical device, comprising:
forming a metasurface comprising a metasurface substrate including at least a first metasurface layer made of a first material, and an array of pillars extending through the first metasurface layer, the pillars being made of a second material different from the first material, the metasurface having a first face and a second face opposite the first face;
forming a first anti-reflection stack over the first face of the metasurface, the first anti-reflection stack having a third face and a fourth face opposite the third face and positioned over the metasurface; and
forming a metal trace having a portion which is exposed at the third face of the first anti-reflection stack.

17. The method of claim 16, wherein forming the metasurface and the first anti-reflection stack comprises:
forming on a silicon wafer a first stack comprising at least a first layer made of a third material different from the first material, the first stack having a fifth face corresponding to a face of the first layer, and a sixth face opposite the fifth face and facing the silicon wafer;
forming the first metasurface layer on the face of the first layer;
forming second openings through the first metasurface layer;
filling the second openings with a filling material to form the array of pillars;
forming a second metasurface layer of the metasurface substrate on the first metasurface layer in order to at least cover the array of pillars;
removing the silicon wafer; and
forming a second stack comprising at least a second layer on the sixth face of the first stack, the first stack and the second stack forming the first anti-reflection stack.

18. The method according to claim 17, wherein the filling material is selected from the group consisting of an amorphous silicon or a polycrystalline silicon.

19. The method according to claim 17, further comprising annealing the filling material

20. The method according to claim 17, wherein forming the metal trace with the exposed portion is performed after the forming of the second metasurface layer and before the removing of the silicon wafer, and comprises:
forming a metal trace in the metasurface substrate;
forming a first opening through the first anti-reflection stack and the metasurface substrate down to the exposed portion of the metal trace.

21. The method according to claim 20, further comprising forming a contact pad in contact with the exposed portion of the metal trace.

22. The method according to claim 17, wherein the forming of the metal trace with the exposed portion is performed after the forming of the second metasurface layer and before the removing of the silicon wafer, and comprises:
forming the metal trace in the second metasurface layer;
forming a third metasurface layer of the metasurface substrate on the second metasurface layer to at least cover the metal trace; and
forming a first opening through the first anti-reflection stack and the metasurface substrate down to the exposed portion of the metal trace.

23. The method according to claim 22, further comprising forming a contact pad in contact with the exposed portion of the metal trace.

24. The method according to claim 16, wherein forming the metal trace with the portion which is exposed comprises forming a metal layer with a contact pad on the first anti-reflection stack, the metal trace corresponding to at least a portion of the metal layer.

25. The method according to claim 17, wherein the first material is selectively etchable with respect to the third material.

26. The method according to claim 25, wherein the first material is a silicon oxide and the third material is a silicon nitride.

27. The method according to claim 16, wherein the pillars are made of polycrystalline silicon, and the metasurface substrate is made of a silicon oxide.

28. The method according to claim 16, wherein the first anti-reflection stack comprises a stack of dielectric layers with alternately high and low refractive indexes.

29. The method according to claim 16, wherein the first anti-reflection stack comprises silicon oxide or silicon oxynitride layers in alternance with silicon nitride layers.

30. The method according to claim 16, wherein the metal trace is formed in the metasurface substrate, the method further comprising: forming an opening through the first anti-reflection stack and metasurface substrate to reach a portion of the metal trace, and forming a contact pad at the opening in contact with the portion of the metal trace.
